(19) United States
(12) Patent Application Publication
(10) Pub. No.: US 2015/0214387 A1
(43) Pub. Date: Jul. 30, 2015

(54) PHOTODETECTOR

(71) Applicant: Electronics and Telecommunications Research Institute, Daejeon (KR)

(72) Inventors: Sae-Kyoung KANG, Daejeon (KR); Sang-Soo LEE, Daejeon (KR)

(21) Appl. No.: 14/592,316

(22) Filed: Jan. 8, 2015

(30) Foreign Application Priority Data
Jan. 24, 2014 (KR) 10-2014-0009157

(51) Int. Cl. H01L 31/028; H01L 31/0232; H01L 31/02; H01L 31/103

(52) U.S. Cl. CPC H01L 31/028; H01L 31/103; H01L 31/02327; H01L 31/02005

(57) ABSTRACT

A photodetector is provided. The photodetector includes first metal layers in which optical signals are converted into electric signals; first vias formed between the first metal layers and doped areas which include doped areas on both ends of an optical waveguide and a doped area on a growing portion, which absorbs a light signal transmitted through the optical waveguide; second metal layer in which optical signals are converted into electric signals; and second vias formed between the first metal layers and the second metal layers.

### CROSS-REFERENCE TO RELATED APPLICATION(S)

This application claims priority under 35 U.S.C. §119(a) from Korean Patent Application No. 10-2014-0009157, filed on Jan. 24, 2014, in the Korean Intellectual Property Office, the entire disclosure of which is incorporated herein by reference for all purposes.

### BACKGROUND

1. Field

The following description relates to an optical device, and more particularly, to a photodetector that converts an optical signal into an electric signal.

2. Description of the Related Art

As optical systems have increased in speed and capacity while decreasing in prices, increasing attention has been drawn to techniques to integrate CMOS photonics-based electronic circuitry and optical circuitry into a single chip. Such techniques have been studied for a decade, and now vendors have emerged to provide foundries using these integration techniques.

Although a high cost is incurred to implement the integration techniques while these techniques remain at a low level, since an optical device is much bigger than a CMOS electronic device, and there is a significant difference in layers between the electronic device manufacturing mask and the optical device manufacturing mask, the integration technique is anticipated to be the core solution for implementation of a compact optical communication system at a low cost.

As a silicon photonics-based optical device, an optical waveguide, an optical splitter and coupler, an optical multiplexer and demultiplexer, a photodetector, a modulator, and other passive devices may be manufactured. Amongst the aforementioned optical devices, the foundry vendors provide the optical waveguide, the photodetector, the modulator, and the optical splitter and coupler as a library.

The photodetector as an essential component of an optical receiver is implemented by growing germanium on silicon. This is because the wavelength (1.3 μm and 1.5 μm) of optical signals used for optical communications falls within the wavelength range that magnesium can absorb. Since the wavelength range of light that silicon is able to absorb is between 400 nm and 700 nm, silicon is not applicable to general optical communications within a long wavelength band.

The photodetector may be implemented as two main types of structure.

First, an evanescent coupling structure may be possible in which a germanium layer is grown on a silicon optical waveguide. In this structure, an optical signal is propagating through the silicon waveguide while the mode is not completely closed, which results in an evanescent coupling to the germanium layer due to a difference in index of refraction. Through such procedures, the optical signal enters a germanium intrinsic layer, and a current signal is generated corresponding to the optical signal, in accordance with an electric bias applied to electrodes (i.e. anode and cathode) of the photodetector formed on the silicon waveguide and germanium layer.

Second, a butt coupling structure may be possible in which germanium is grown on silicon on an end of an optical waveguide through which an optical signal is propagated. In this structure, the optical signal propagating through the silicon optical waveguide directly enters a germanium layer and then is coupled to the germanium layer. The subsequent basic operations of the butt-coupled photodetector are the same as those of the evanescent-coupled photodetector.

In the process of growing germanium on silicon for the photodetector, dislocation occurs at the interface between germanium and silicon since there is a lattice constants difference greater than 4% between germanium and silicon. This dislocation causes a leakage current, resulting in a deterioration of the dark current properties, which are performance parameters of the photodetector. Another cause of the dark current is leakage current occurring at the interface between a metal and a semiconductor during the ohmic contact formation between the metal and the semiconductor (p-type or n-type doped area in silicon or germanium region of the photodector), and the leakage current is in proportion to the size of the contacting area between the germanium and the silicon.

### SUMMARY

The following description relates to a photodetector capable of improving dark currents and responsivity by reducing an area of contact and increasing the via resistance between a metal and a semiconductor.

Other features and aspects may be apparent from the following detailed description, drawings, and claims.

### BRIEF DESCRIPTION OF THE DRAWINGS

FIG. 1 is a diagram illustrating an example of an evanescent-coupled photodetector.

FIG. 2 is a diagram illustrating an example of a structure of a butt-coupled photodetector.

FIG. 3 is a diagram illustrating a structure of a photodetector according to an exemplary embodiment.

FIG. 4A is a cross-sectional view of the photodetector of FIG. 3.

FIG. 4B is a top-view of the photodetector of FIG. 3.

FIGS. 5A to 5C are diagrams of three photodetectors with different via structures.

FIG. 6A is a graph showing the result of measuring dark currents of the three photodetectors in different structures.

FIG. 6B is a graph showing the result of measuring the responsivity of each photodetector to incident light.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

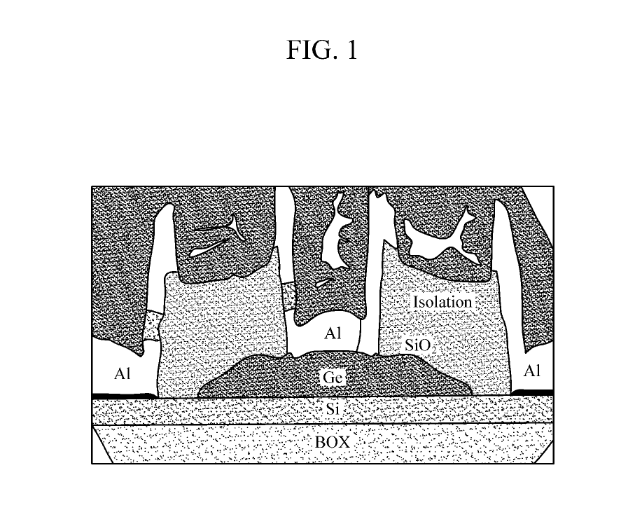

FIG. 1 is a diagram illustrating an example of an evanescent-coupled photodetector.

Referring to FIG. 1, a structure of a photodetector, developed by the Institute of Microelectronics in Singapore, is illustrated to show that a metal (Aluminum) is formed as a single via with a length corresponding to a length of the photodetector when connected to parts doped with different types within silicon and germanium regions. In this case, while a via resistance is reduced, a leakage current is disadvantageously increased due to an increase in the contacting area between the two materials.

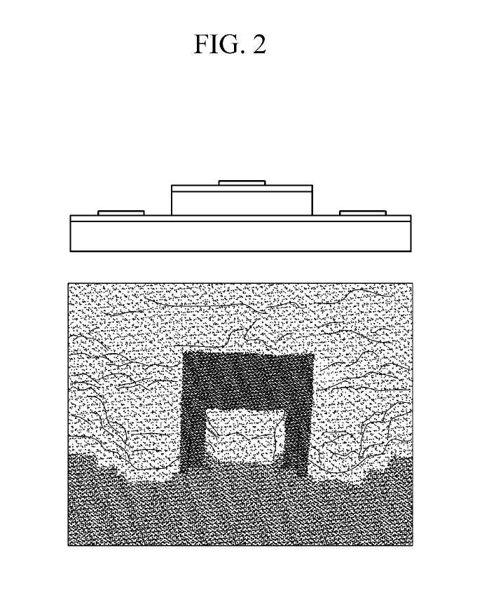

FIG. 2 is a diagram illustrating an example of a structure of a butt-coupled photodetector.

Referring to FIG. 2, a structure of a photodetector, which has been developed by the Institut d'Electronique Fondamental (IEF) and CEA-Leti in France as a part of the European HELIOS project, is illustrated in which a signal via with a length corresponding to a length of the photodetector is formed to connect metal and areas doped with different types within the silicon and germanium regions. This structure also has a reduced via resistance, but leakage current is increased due to an increase in the contacting area between germanium and silicon.

In the exemplary embodiments described herein, a structure is suggested in which the vias are stacked in two or more layers so as to minimize the contacting area between the two materials. For convenience of description, a via structure of an evanescent-coupled photodetector is described hereinafter, but the via structure in accordance with the exemplary embodiments herein is applicable to a butt-coupled photodetector.

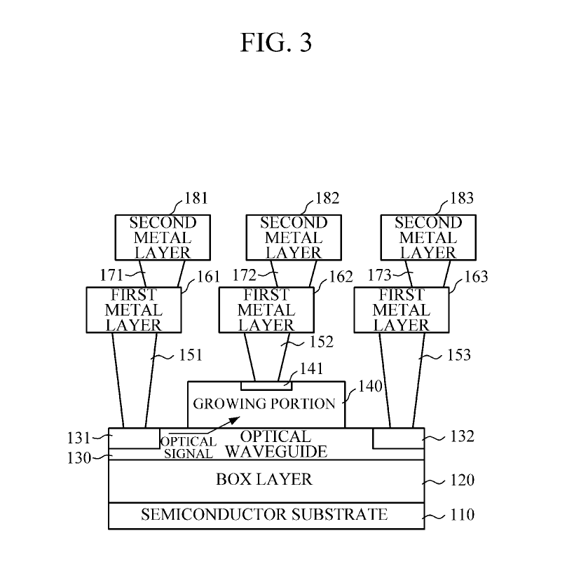

FIG. 3 is a diagram illustrating a structure of a photodetector according to an exemplary embodiment.

Referring to FIG. 3, the photodetector includes a semiconductor substrate 110, a buried oxide (BOX) layer 120 formed on an upper surface of the semiconductor substrate 110, an optical waveguide 130 that is formed on an upper surface of the BOX layer 120 and allows a light signal to pass therethrough, a growing portion 140 on an upper part of the optical waveguide 130, which grows with a material other than that of the optical waveguide 130 and absorbs a light signal, doped areas 131, 132, and 141 which are, respectively, doped on predetermined parts of both ends of the optical waveguide 130 and the growing portion 140, first metal layers 161, 162, and 163, first vias 151, 152, and 153 disposed between the respective doped areas 131, 132, and 141 and the respective first metal layers 161, 162, and 163, second metal layers 181, 182, and 183, and second vias 171, 172, and 173 disposed between the respective first metal layers 161, 162, 163 and the respective second metal layers 181, 182, and 183.

The semiconductor substrate 110 and the optical waveguide 130 may be made of silicon, and the growing portion 140 may be formed of germanium. The semiconductor substrate 110, the BOX layer 120, and the optical waveguide 130 are well-known, and thus the detailed description thereof will be omitted.

An optical signal propagates through the optical waveguide 130 in the photodetector, and then it is optically coupled to the growing portion 140 in a wider width of the silicon optical waveguide 130, wherein most of the optical signal is optically coupled to the growing portion 140 while propagating between two layers in a zigzag manner.

The doped areas 131, 132, and 141 are parts that are doped with p-type (generally, boron doping) or n-type (generally, phosphorus doping) in order to form electrodes of a photodetector. Here, the doping concentration needs to be doped to conform to requirements for ohmic contact between the doped areas 131, 132, and 141 and the first vias 151, 152 and 153. Otherwise, the contact resistance at the interfaces between the doped areas 131, 132, and 141 and the first vias 151, 152, and 153 will be significantly increased.

The growing portion 140 may be doped with n-type (generally, phosphorus doping) or p-type (generally, boron doping) in order to form an electrode with a polarity opposite to that of an electrode of the optical waveguide 130 of the photodetector. In this case, the doping concentration is set to conform to the same ohmic contact requirements needed for the electrode formation in the optical waveguide 130.

In the exemplary embodiments, the first vias 161, 162, and 163 and the second vias 171, 172, and 173 may be arranged to be stacked vertically or in a non-overlapping manner depending on the manufacturing process.

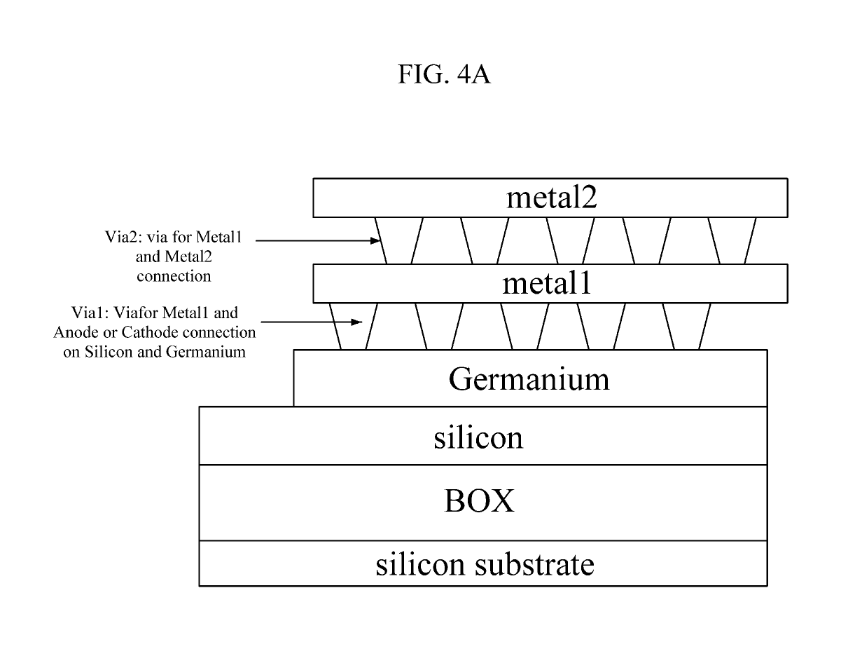

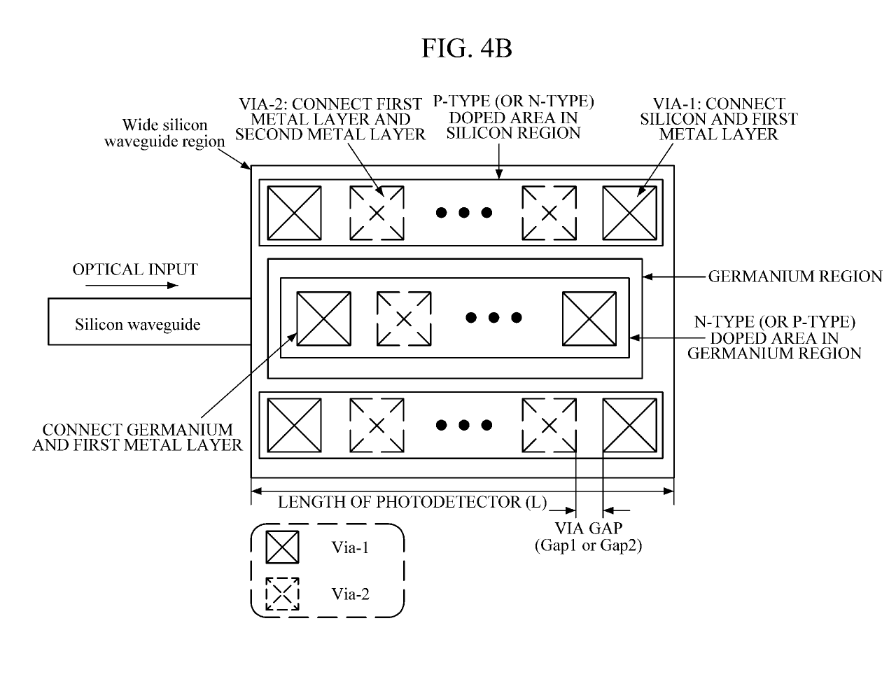

FIGS. 4A and 4B are diagrams illustrating a cross-sectional view and a top view of a photodetector when the vias are stacked in a non-overlapping manner.

FIGS. 4A and 4B illustrates that the semiconductor substrate and the light waveguide are made of silicon, and the growing portion is made of germanium, but the aspects of the exemplary embodiment are not limited thereto.

Referring to FIGS. 4A and 4B, the first vias are spaced apart from each other at a distance corresponding to the size of the second via. That is, in order to reduce the via resistance of the first vias within the same manufacturing conditions, more first vias are disposed by setting the distance between the first vias to the minimum manufacturable distance, and the first metal layers are connected to the second metal layers using the second vias in a chip pad area of the photodetector.

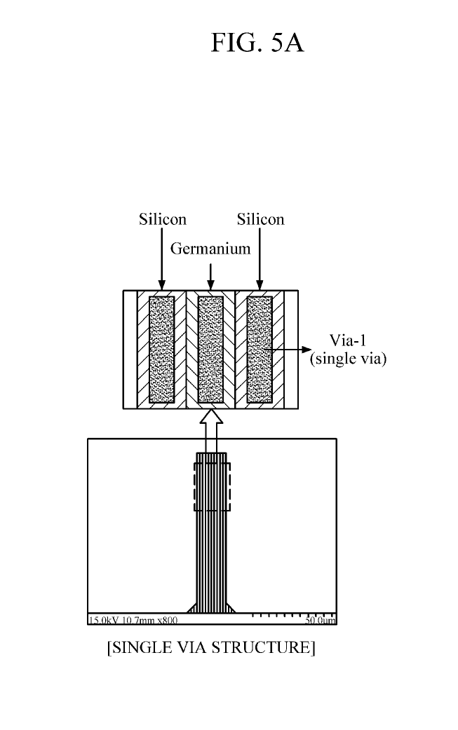

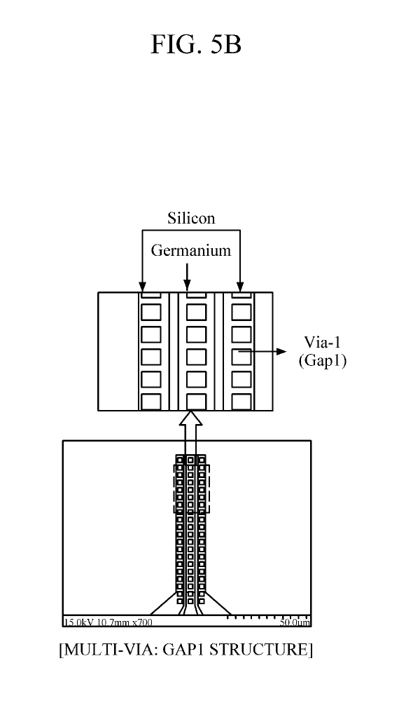

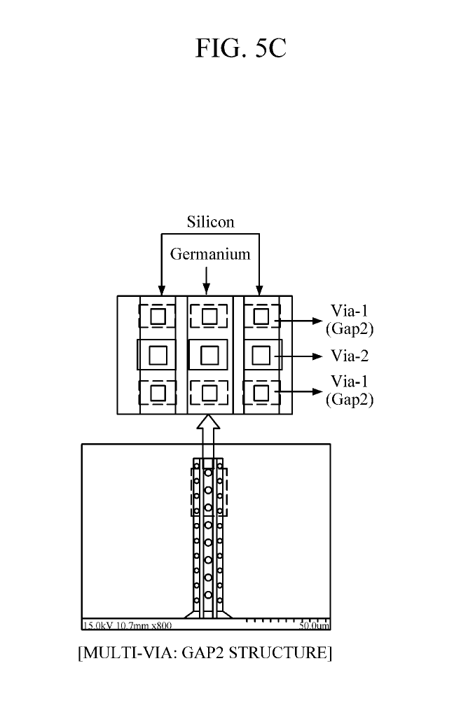

FIGS. 5A to 5C are diagrams of three photodetectors with different via structures.

Referring to 5A, there is illustrated a structure in which a first via in the form of a single via is stacked on the photodetector and a second via is formed on a chip pad area of the photodetector.

Referring to FIG. 5B, there is illustrated a structure in which only a first via is stacked on the photodetector and a second via is disposed on a chip pad area of the photodetector.

Referring to FIG. 5C, a first via and a second via are stacked on the photodetector in such a manner that they do not overlap each other.

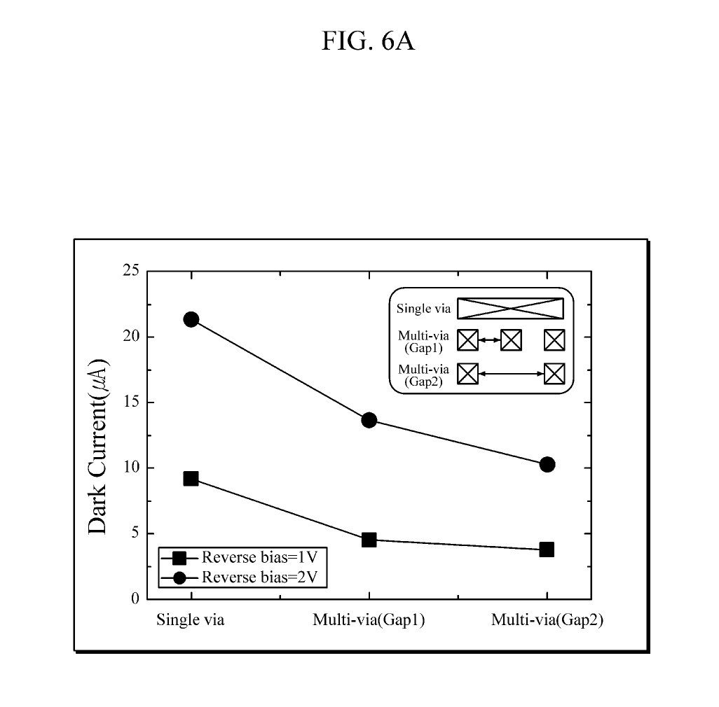

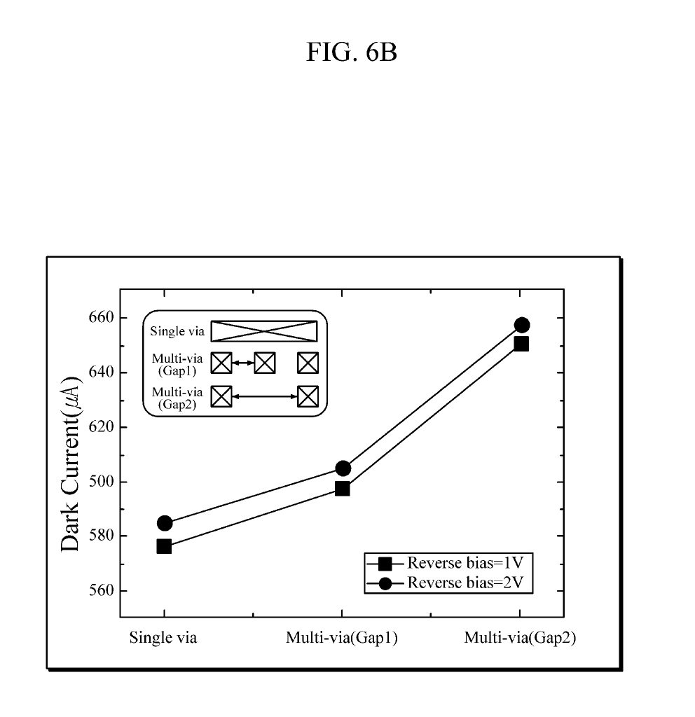

FIG. 6A is a graph showing the result of measuring dark currents of the three photodetectors in different structures, and FIG. 6B is a graph showing the result of measuring the responsivity of each photodetector to incident light. In this case, the measurement condition is that reverse bias is should be applied to each electrode (anode and cathode) of the photodetector until it reaches 1 V and 2 V at each electrode.

Referring to FIG. 6A, it is noted that a dark current of the photodetector, employing a structure in which a multi-via is chosen as the first via, is reduced when compared to a case where the first via is provided in the form of a single via. Even among the photodetectors with multi-via structures, a structure (multi-via:Gap2) in which the first via and the second via are stacked in a non-overlapping manner exhibits the lowest dark current.

It appears that this is due to the difference in the leak current in accordance with a contacting area between the first metal layer (metal-1) and the semiconductor (a doped area for forming electrodes of silicon and germanium).

Referring to FIG. 6B, more improved values are exhibited in terms of responsivity, in comparison to the three structures with respect to the dark current. This phenomenon is caused because an optical signal is converted into a current signal in the photodetector, and the instantly-converted current is prevented from locally increasing current density through a plurality of vias. Specifically, the structure in which the first via and the second via are arranged to be stacked in a non-overlapping manner exhibits an improved responsivity since the second metal layer with a lower resistance than that of the first metal layer is stacked on the photodetector using a plurality of second vias, and it outputs a current signal collected in the first metal layer without a loss.

A number of examples have been described above. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A photodetector comprising:
first metal layers in which optical signals are converted into electric signals;
first vias formed between the first metal layers and doped areas which include doped areas on both ends of an optical waveguide and a doped area on a growing portion, which absorbs a light signal transmitted through the optical waveguide;
second metal layers in which optical signals are converted into electric signals; and
second vias formed between the first metal layers and the second metal layers.

2. The photodetector of claim 1, wherein the optical waveguide and the growing portion are evanescently coupled or butt-coupled to each other.

3. The photodetector of claim 1, wherein the optical waveguide is made of silicon.

4. The photodetector of claim 1, wherein the growing portion is made of germanium.

5. The photodetector of claim 1, wherein the first vias and the second vias are vertically aligned with each other.

6. The photodetector of claim 1, wherein the first vias and the second vias are disposed in a manner that they do not overlap each other.

7. The photodetector of claim 6, wherein a distance between the first vias corresponds to a size of the second vias and a distance between the second vias corresponds to a size of the first vias.
